(19) United States
(12) Patent Application Publication
(10) Pub. No.: US 2026/0161075 A1
(43) Pub. Date: Jun. 11, 2026

(54) PHOTOSENSITIVE ELEMENT, AND METHOD FOR FORMING RESIST PATTERN

(71) Applicant: ASAHI KASEI KABUSHIKI KAISHA, Tokyo (JP)

(72) Inventor: Yoshitaka KAMOCHI, Tokyo (JP)

(73) Assignee: ASAHI KASEI KABUSHIKI KAISHA, Tokyo (JP)

(21) Appl. No.: 18/704,386

(22) PCT Filed: Oct. 7, 2022
(86) PCT No.: PCT/JP2022/037657

§ 371 Date: Apr. 24, 2024

(30) Foreign Application Priority Data
Oct. 25, 2021 (JP) 2021-173949

(51) Int. Cl. G03F 7/028; C08K 5/13; G03F 7/033; G03F 7/09; H05K 3/00

(52) U.S. Cl. CPC G03F 7/028; C08K 5/13; G03F 7/033; G03F 7/09; H05K 3/0076

(57) ABSTRACT

The present invention provides: a photosensitive element which exhibits rinse aid properties for a developer solution after a development device is stopped; and a method for forming a resist pattern. The present invention provides a photosensitive element which is provided with a supporting film and a photosensitive resin composition laver that is formed on the supporting film and contains a photosensitive resin composition, wherein: the photosensitive resin composition contains (A) an alkali-soluble polymer, (B) a compound having an ethylenically unsaturated double bond, (C) a sensitizing agent and (D) a polymerization inhibitor; the alkali-soluble polymer (A) contains an alkali-soluble polymer, a monomer component of which contains an aromatic hydrocarbon group, and which has a weight average molecular weight Mw of 20,000 or less; and the compound (B) having an ethylenically unsaturated double bond is a compound which has a structure represented by general formula (B1).

### FIELD

The present invention relates to a photosensitive element and to a resist pattern forming method.

### BACKGROUND

Printed circuit boards are generally manufactured by photolithography. Photolithography is a method of forming a desired wiring pattern on a substrate by a process involving the following steps. First, a layer of a photosensitive resin composition is formed on a substrate, and a resist pattern is formed by pattern exposure and development of the coated film. Etching or plating treatment is then carried out to form a conductor pattern. The resist pattern on the substrate is subsequently removed to form the desired wiring pattern on the substrate.

It is common to use photosensitive elements (photosensitive resin laminates) for production of printed circuit boards. A large variety of known methods exist for forming circuit patterns using photosensitive elements, each employing photosensitive resin compositions that are suited for the respective methods (PTLs 1 to 4).

### CITATION LIST

### Patent Literature

[PTL 1] Japanese Unexamined Patent Publication No. 2012-037872
[PTL 2] WO2016/104639
[PTL 3] Japanese Unexamined Patent Publication No. 2018-136531
[PTL 4] WO2019/244724

### SUMMARY

### Technical Problem

All of the materials described in PTLs 1 to 4, however, still have room for improvement in terms of developability, resolution, flexibility, and foamability of the developing solution.

For example, using a low molecular high-styrene polymer as the binder polymer in the photosensitive resin composition results in excellent resolution, but an inherent problem has been foaming of the developing solution during spray development, with the generated air bubbles failing to satisfactorily disappear after shutdown of the developing device (poor foam removal).

This is thought to occur because the air bubbles generated during spraying of the developing solution become stabilized by surface tension of the developing solution in which the resist is dissolved.

Strategies for inhibiting foaming of the developing solution during development have been investigated, but they have not been focused on satisfactorily eliminating the foam after development.

The present invention has been devised in light of this situation of the prior art, and its object is to provide a photosensitive element, and resist pattern forming method, with satisfactory elimination of foam from the developing solution after the developing device has stopped.

### Solution to Problem

The present inventors have found that the aforementioned object can be achieved by the following technical means, and the invention has thereupon been completed. The present invention is as follows.

A photosensitive element comprising a support film and a photosensitive resin composition layer containing a photosensitive resin composition, formed on the support film, wherein: the photosensitive resin composition comprises:
(A) an alkali-soluble polymer,
(B) a compound with an ethylenically unsaturated double bond,
(C) a sensitizing agent, and
(D) a polymerization inhibitor,
   the alkali-soluble polymer (A) includes an alkali-soluble polymer in which the monomer component comprises an aromatic hydrocarbon group and which has a weight-average molecular weight Mw of 20,000 or lower, and
the compound with an ethylenically unsaturated double bond (B) is a compound having the structure represented by the following general formula (B1):

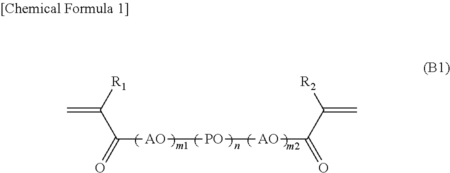

(where R₁ and R₂ each independently represent hydrogen or carbon, A is a divalent hydrocarbon group of 1 to 2 carbon atoms, P is a divalent hydrocarbon group of 3 carbon atoms, the sequence of (AO) and (PO) is random or block, m1+m2 is an integer of 0 to 10, and n is an integer of 1 to 30).

The photosensitive element according to [1] above, wherein n in general formula (B1) is 2 to 15.

The photosensitive element according to [1] or [2] above, wherein n in general formula (B1) is 3 to 8.

The photosensitive element according to any one of [1] to [3] above, wherein (m1+m2)/n in general formula (B1) is less than 0.83.

The photosensitive element according to any one of [1] to [4] above, wherein (m1+m2)/n in general formula (B1) is less than 0.50.

The photosensitive element according to any one of [1] to [5] above, wherein the content of the compound with an ethylenically unsaturated double bond (B1) is 0.1 to 10 parts by weight based on the sum of the alkali-soluble polymer (A) and the compound with an ethylenically unsaturated double bond (B).

The photosensitive element according to any one of [1] to [6] above, wherein the alkali-soluble polymer (A) includes an alkali-soluble polymer which has a weight-average molecular weight Mw of 8,000 or greater.

The photosensitive element according to any one of [1] to [7] above, wherein the aromatic hydrocarbon group included as the monomer component of the alkali-soluble polymer (A) is 1 to 70 parts by weight based on the total amount of the alkali-soluble polymer (A).

The photosensitive element according to any one of [1] to [8] above, wherein the aromatic hydrocarbon group included as the monomer component of the alkali-soluble polymer (A) is 10 to 60 parts by weight based on the total amount of the alkali-soluble polymer (A).

The photosensitive element according to any one of [1] to [9] above, wherein the compound with an ethylenically unsaturated double bond (B) further comprises one or more compounds having the structure represented by general formula (B2) or (B3):

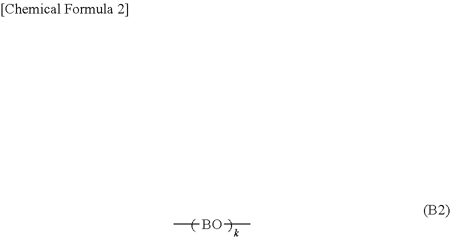

(where B is a divalent hydrocarbon group of 4 carbon atoms, and k is an integer of 1 to 30),

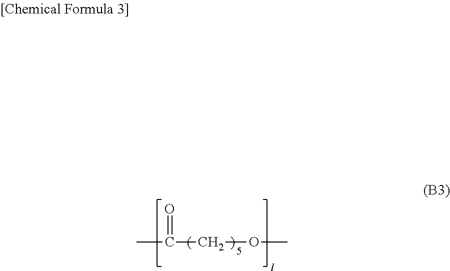

(where 1 is an integer of 1 to 30).

The photosensitive element according to [10] above, wherein at least one of compound (B2) or (B3) having an ethylenically unsaturated double bond has 3 or more ethylenically unsaturated double bonds per molecule.

The photosensitive element according to any one of [1] to [11] above, which further comprises a compound comprising a hydrogenated bisphenol A structure (B4), as the compound with an ethylenically unsaturated double bond (B).

The photosensitive resin composition according to any one of [1] to [12] above, wherein the sensitizing agent (C) includes a benzophenone compound.

The photosensitive element according to any one of [1] to [13] above, wherein the polymerization inhibitor (D) includes 2,6-di-tert-butyl-para-cresol.

A resist pattern forming method, comprising:
a lamination step in which the photosensitive element according to any one of [1] to [14] is laminated on a substrate;
an exposure step in which the photosensitive resin layer of the photosensitive resin laminate is exposed; and
a developing step in which the unexposed sections of the photosensitive resin layer are developed and removed.

### Advantageous Effects of Invention

According to the invention it is possible to provide a photosensitive element, and resist pattern forming method, with satisfactory elimination of foam from the developing solution after the developing device has stopped.

### DESCRIPTION OF EMBODIMENTS

Exemplary embodiments of the invention (hereunder abbreviated as “embodiments”) will now be described in detail. The invention is not limited to the embodiments, and various modifications may be implemented within the scope of the gist thereof. The upper limits and lower limits for the numerical ranges throughout the present specification may be combined as desired.

Incidentally, the numerical ranges indicated herein using the connecting preposition “to” include both the upper and lower limiting values.

The photosensitive element of the invention comprises a support film, and a photosensitive resin composition layer containing a photosensitive resin composition, formed on the support film.

The photosensitive element of the invention is particularly characterized in that the photosensitive resin composition comprises:
(A) an alkali-soluble polymer,
(B) a compound with an ethylenically unsaturated double bond,
(C) a sensitizing agent, and
(D) a polymerization inhibitor,
   the alkali-soluble polymer (A) includes an alkali-soluble polymer in which the monomer component comprises an aromatic hydrocarbon group and which has a weight-average molecular weight Mw of 20,000 or lower, and
the compound with an ethylenically unsaturated double bond (B) is a compound having the structure represented by the following general formula (B1):

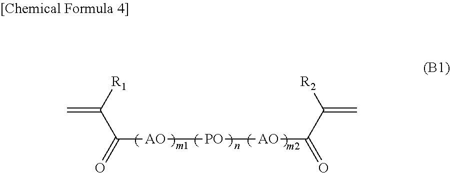

(where R₁ and R₂ each independently represent hydrogen or carbon, A is a divalent hydrocarbon group of 1 to 2 carbon atoms, P is a divalent hydrocarbon group of 3 carbon atoms, the sequence of (AO) and (PO) is random or block, m1+m2 is an integer of 0 to 10, and n is an integer of 1 to 30).

The present inventors imagined that by properly controlling the repeating units of the PO (propylene oxide) structure in the compound with an ethylenically unsaturated double bond (B), not only would foaming be prevented during operation of the development device, but elimination of foam after stopping of the device would also be satisfactory.

In other words, according to the invention it is possible to provide a photosensitive element, and resist pattern forming method, with reduced foaming of the developing solution during development, and particularly with satisfactory elimination of foam after the developing device has stopped. The present invention is focused on the novel effect of satisfactory foam elimination.

### <Support Film>

The support film of the embodiment is a layer or film for support of the photosensitive resin composition layer, and it is preferably a transparent base film that allows active light rays to pass through.

Transparent base films include films composed of synthetic resins such as polyethylene, polypropylene, polycarbonate and polyethylene terephthalate. It is generally preferred to use polyethylene terephthalate (PET), which has suitable flexibility and strength.

It is preferred to use a high quality film with minimal interior contaminants. Specifically, a high quality film is more preferably a PET film synthesized using a Ti-based catalyst, a PET film having a small lubricant diameter and low content, a PET film comprising a lubricant only on one side of the film, a thin-film PET film, a PET film processed by smoothing on at least one side, or a PET film roughened by plasma treatment on at least one side.

This will allow exposure light to be irradiated onto the photosensitive resin composition layer without being blocked by interior contaminants, so that the developing resolution of the photosensitive element can be increased.

The thickness of the support film is preferably 5 μm to 25 μm and more preferably 6 μm to sm. A smaller thickness of the support film can reduce the number of interior contaminants and prevent reduction in resolution, but a film thickness of less than 5 μm tends to result in tearing due to elongation deformation or minute damage in the direction of winding under tension during the production steps of coating and winding, and also tends to result insufficient film strength which can lead to wrinkles during lamination.

Smoothing treatment using a calender apparatus may be carried out on at least one side of the support film. This can reduce surface roughness on one side of the support film, and especially the side that contacts with the photosensitive resin composition layer, allowing a superior effect of the invention to be exhibited.

The haze of the support film is preferably 0.01% to 1.5%, more preferably 0.01% to 1.2% and even more preferably 0.01 to 0.95%, from the viewpoint of improving parallelism of the light rays irradiated onto the photosensitive resin composition layer, and obtaining higher resolution after exposure and development of the photosensitive element.

### <Photosensitive Resin Composition Layer>

The photosensitive resin composition layer is laminated on the support film. The photosensitive resin composition layer of the embodiment comprises (A) an alkali-soluble polymer, (B) a compound with an ethylenically unsaturated double bond, (C) a sensitizing agent and (D) a polymerization inhibitor.

### (A) Alkali-Soluble Polymer

According to this embodiment, a structural unit of a monomer component having an aromatic hydrocarbon group is included as the alkali-soluble polymer (A), from the viewpoint of excellent adhesiveness and resolution.

Examples of such aromatic hydrocarbon groups include substituted or unsubstituted phenyl groups, and substituted or unsubstituted aralkyl groups. From the same viewpoint, a monomer component with an aromatic hydrocarbon group is preferably a monomer with a substituted or unsubstituted benzyl group (such as benzyl (meth)acrylate), a styrene derivative (such as styrene, methylstyrene, vinyltoluene, tert-butoxystyrene, acetoxystyrene, 4-vinylbenzoic acid, styrene dimer or styrene trimer), more preferably a styrene derivative, and most preferably styrene.

The content ratio of the monomer component with an aromatic hydrocarbon group in the alkali-soluble polymer (A) is preferably 52 weight % or greater, more preferably 55 weight % or greater, even more preferably 57 weight % or greater, especially preferably 58 weight % or greater and most preferably 60 weight % or greater, based on the total weight of all of the monomer components.

There is no particular restriction on the upper limit, but it is preferably 95 weight % or lower and more preferably 80 weight % or lower.

The aromatic hydrocarbon groups as monomer components in the alkali-soluble polymer (A) are preferably included at 1 to 70 parts by weight and more preferably 10 to 60 parts by weight based on the total alkali-soluble polymer (A) (100 parts by weight).

The alkali-soluble polymer (A) comprising a monomer component with an aromatic hydrocarbon group is preferably obtained by polymerizing a monomer with an aromatic hydrocarbon group with one or more of the first monomers mentioned below and/or one or more of the second monomers mentioned below.

The alkali-soluble polymer (A) is preferably obtained by polymerization of one or more of the first monomers described below, and more preferably it is obtained by copolymerization of one or more of the first monomers and one or more of the second monomers described below.

The first monomer is a monomer containing a carboxyl group in the molecule. Examples for the first monomer include (meth)acrylic acid, fumaric acid, cinnamic acid, crotonic acid, itaconic acid, 4-vinylbenzoic acid, maleic anhydride and maleic acid half esters. Of these, (meth)acrylic acid is preferred and methacrylic acid is more preferred, from the viewpoint of excellent adhesiveness and resolution.

As used herein, “(meth)acrylic acid” means acrylic acid or methacrylic acid, “(meth)acryloyl group” means an acryloyl or methacryloyl group, and (meth)acrylate means acrylate or methacrylate.

The copolymerization ratio of the first monomer is preferably 10 to 50 weight % based on the total weight of the total monomer components. A copolymerization ratio of 10 weight % or greater is preferred from the viewpoint of excellent adhesiveness and resolution, with 15 weight % or greater being more preferred, 18 weight % or greater being even more preferred, 21 weight % or greater being yet more preferred, 23 weight % or greater being especially preferred and 24 weight % or greater being most preferred. A copolymerization ratio of 50 weight % or lower is also preferred from the viewpoint of excellent adhesiveness and resolution, with 35 weight % or lower being more preferred, 30 weight % or lower being even more preferred, 29 weight % or lower being yet more preferred, 27 weight % or lower being especially preferred and 26 weight % or lower being most preferred.

The second monomer is a monomer that is non-acidic and has at least one polymerizable unsaturated group in the molecule. Examples for the second monomer include (meth)acrylates such as methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, 2-hydroxyethyl (meth)acrylate, 2-hydroxypropyl (meth)acrylate, cyclohexyl (meth)acrylate and 2-ethylhexyl (meth)acrylate; vinyl alcohol esters such as vinyl acetate; and (meth)acrylonitrile. Preferred among these are methyl (meth)acrylate, 2-ethylhexyl (meth)acrylate and n-butyl (meta)acrylate.

From the viewpoint of excellent adhesiveness and resolution, the alkali-soluble polymer (A) preferably includes 1 to 20 weight % of a structural unit derived from an alkyl ester (4 or more carbon atoms for an alkyl (meth)acrylate), as the second monomer. From the same viewpoint, the amount is preferably 3 weight % or greater and more preferably 5 weight % or greater, and
preferably 15 weight % or lower, more preferably 10 weight % or lower, especially preferably 8 weight % or lower and most preferably 6 weight % or lower.

The alkali-soluble polymer (A) includes an alkali-soluble polymer with a weight-average molecular weight Mw of 20,000 or lower, and preferably the alkali-soluble polymer (A) includes an alkali-soluble polymer with a weight-average molecular weight Mw of 8,000 or greater.

The weight-average molecular weight Mw of the alkali-soluble polymer (A) is preferably 8,000 to 20,000. The weight-average molecular weight Mw is preferably 20,000 or lower from the viewpoint of excellent adhesiveness and resolution, and from the same viewpoint it is more preferably 18,000 or lower and even more preferably 15,000 or lower.

From the same viewpoint, the weight-average molecular weight Mw is preferably 8,000 or higher, more preferably 10,000 or higher and even more preferably 12,000 or higher.

The dispersity of the alkali-soluble polymer (A) is preferably 1.0 to 6.0, more preferably 1.0 to 5.0, even more preferably 1.0 to 4.0 and most preferably 1.0 to 3.0.

The alkali-soluble polymer (A) used may be of a single type, or a mixture of two or more different types may be used.

Synthesis of the alkali-soluble polymer (A) is preferably accomplished by adding an appropriate amount of a radical polymerization initiator such as benzoyl peroxide or azoisobutyronitrile to a solution containing one or more of the monomers mentioned above diluted with a solvent such as acetone, methyl ethyl ketone or isopropanol, and heating and stirring the mixture. The synthesis may also be carried out while adding a portion of the mixture dropwise to the reaction mixture. Upon completion of the reaction, additional solvent may be added for adjustment to the desired concentration. The synthesis means used may be bulk polymerization, suspension polymerization or emulsion polymerization, instead of solution polymerization.

The proportion of the alkali-soluble polymer (A) with respect to the total solid weight of the photosensitive resin composition may be 10 weight % or greater, 20 weight % or greater, 25 weight % or greater, 30 weight % or greater, 35 weight % or greater, 40 weight % or greater, 45 weight % or greater, 50 weight % or greater, 55 weight % or greater or 60 weight % or greater. It may also be 90 weight % or lower, 80 weight % or lower, 70 weight % or lower, 60 weight % or lower or 50 weight % or lower.

The proportion of the alkali-soluble polymer (A) with respect to the photosensitive resin composition is preferably no greater than 90 weight % from the viewpoint of controlling the developing time. On the other hand, the proportion of the alkali-soluble polymer (A) with respect to the photosensitive resin composition is preferably at least 10 weight % from the viewpoint of improving resistance to edge fusing.

Compound with an Ethylenically Unsaturated Double Bond (B)

According to this embodiment, the compound with an ethylenically unsaturated double bond (B) is a compound having the structure represented by the following general formula (B1):

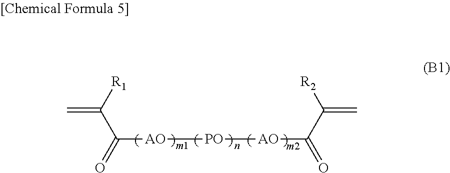

(where R₁ and R₂ each independently represent hydrogen or carbon. A is a divalent hydrocarbon group of 1 to 2 carbon atoms, P is a divalent hydrocarbon group of 3 carbon atoms, the sequence of (AO) and (PO) is random or block, m1+m2 is an integer of 0 to 10, and n is an integer of 1 to 30).

From the viewpoint of developability and flexibility, m1+m2 in formula (B1) is preferably 0 or greater, while from the viewpoint of resolution it is preferably 10 or less.

From the viewpoint of resolution, and of inhibiting foaming of the developing solution and eliminating foam after stopping, n in general formula (B1) is preferably 2 to 15 and more preferably 3 to 8.

This will help to provide a photosensitive resin composition that has satisfactory sensitivity, resolution and adhesiveness and can shorten the stripping time, while allowing formation of a resist pattern with excellent flexibility.

From the viewpoint of resolution, and of inhibiting foaming of the developing solution and eliminating foam after stopping, (m1+m2)/n in general formula (B1) is preferably less than 0.83, and more preferably (m1+m2)/n is less than 0.5.

This will help to provide a photosensitive resin composition that has more satisfactory sensitivity, resolution and adhesiveness and can more effectively shorten the stripping time, while allowing formation of a resist pattern with more excellent flexibility.

The proportion of the compound with an ethylenically unsaturated double bond (B) with respect to the total solid weight of the photosensitive resin composition is preferably 30 weight % or greater and more preferably 35 weight % or greater, from the viewpoint of the sensitivity, tack and follow property. From the viewpoint of the edge fusion property, tack and resolution it is preferably 50 weight % or lower, 45 weight % or lower or 42 weight % or lower.

Moreover from the viewpoint of the edge fusion property, tack and resolution, the solid content of the compound with an ethylenically unsaturated double bond (B) with respect to the solid content of the alkali-soluble polymer (A) in the photosensitive resin composition (that is, “solid content of compound with ethylenically unsaturated double bond (B)/solid content of alkali-soluble polymer (A)”) is preferably 1.4 or lower, 1.3 or lower, 1.2 or lower or 1.1 or lower. The lower limit is preferably 0.7 or higher, 0.8 or higher, 0.9 or higher, or 1.0 or higher.

The proportion of the compound represented by general formula (B1) as the compound with an ethylenically unsaturated double bond (B) is preferably 3 weight % to 30 weight % with respect to the total solid weight of the photosensitive resin composition. The proportion is preferably 2 weight % or greater, and especially 3 weight % or greater, and more preferably 5 weight % or greater, from the viewpoint of resolution, adhesiveness and flexibility.

From the viewpoint of resolution and adhesiveness, the proportion is also preferably 30 weight % or lower, and more preferably 25 weight % or lower.

The proportion of a compound represented by general formula (1) as the compound with an ethylenically unsaturated double bond (B) with respect to the total solid weight of the photosensitive resin composition is especially preferably 17 weight % or lower, 15 weight % or lower, 13 weight % or lower or 10 weight % or lower, from the viewpoint of resolution and adhesiveness.

The content of the compound with an ethylenically unsaturated double bond (B) is preferably 0.1 to 10 parts by weight and more preferably 0.5 to 7 parts by weight, with respect to the sum of the alkali-soluble polymer (A) and the compound with an ethylenically unsaturated double bond (B) (100 parts by weight). This can effectively inhibit foaming of the developing solution during development, and will result in more satisfactory elimination of foam after the developing device has stopped.

The photosensitive resin composition of the embodiment preferably further comprises, as the compound with an ethylenically unsaturated double bond (B), one or more compounds having the structure represented by general formula (B2) or (B3):

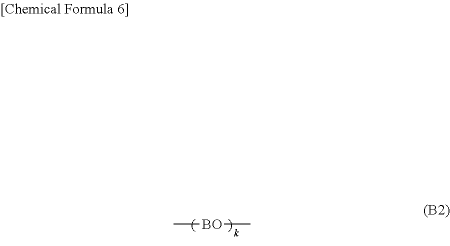

(where B is a divalent hydrocarbon group of 4 carbon atoms, and k is an integer of 1 to 30),

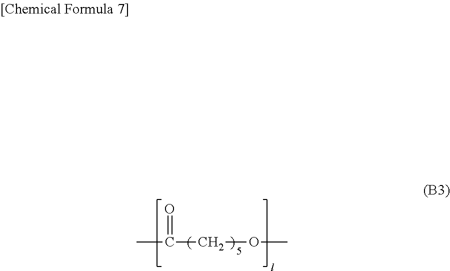

(where 1 is an integer of 1 to 30). This will help to provide a photosensitive resin composition that has satisfactory resolution and adhesiveness while allowing formation of a resist pattern with excellent flexibility.

One or more compounds having the structure represented by general formula (B2) or (B3) preferably have 3 or more ethylenically unsaturated double bonds per molecule. This will help to provide a photosensitive resin composition that has satisfactory resolution and adhesiveness while allowing formation of a resist pattern with excellent developability.

The photosensitive resin composition of the embodiment preferably further comprises, as the compound with an ethylenically unsaturated double bond (B), a compound (B4) comprising a hydrogenated bisphenol A structure, obtained by hydrogenating bisphenol A.

The proportion of compound (B4) comprising a hydrogenated bisphenol A structure used in the photosensitive resin composition of the embodiment is preferably 12 weight % to 45 weight %, more preferably 17 weight % to 40 weight % and even more preferably 20 weight % to weight %, with respect to the total solid weight of the photosensitive resin composition. Use in this proportion range is preferred from the viewpoint of obtaining a photosensitive resin composition with an excellent balance between resolution and developability. If the content of compound (B4) having a hydrogenated bisphenol A structure in the total compound with an ethylenically unsaturated double bond (B) is 40 weight % or greater, the balance between resolution and adhesiveness will be more excellent.

The photosensitive resin composition of the invention preferably has 0.1 to 0.3 moles of ethylenically unsaturated double bonds per 100 g solid weight of the photosensitive resin composition. If the number of moles is 0.1 or greater, it will be possible to prevent elution of the photosensitive resin component from the cured photosensitive resin composition (resist pattern) during the rinsing step after development, which causes contamination of the rinsing step. If the number of moles is 0.3 or lower, it will be possible to prevent chipping and shedding of the cured photosensitive resin composition (resist pattern) during the rinsing step after development, which likewise causes contamination of the rinsing step.

The number of moles of ethylenically unsaturated double bonds per 100 g solid content of the photosensitive resin composition is preferably 0.1 or greater, more preferably 0.11 or greater, even more preferably 0.12 or greater and yet more preferably 0.13 or greater. It is also preferably 0.3 or lower, 0.28 or lower, 0.25 or lower, 0.22 or lower, 0.20 or lower, 0.18 or lower or 0.15 or lower.

It is preferably 0.1 to 0.25, more preferably 0.1 to 0.2, even more preferably 0.11 to 0.2 and especially preferably 0.11 to 0.15.

### (C) Sensitizing Agent

The sensitizing agent (C) may be a pyrazoline derivative, an anthracene derivative, a triarylamine derivative, an oxazole derivative, an N-aryl-α-amino acid derivative other than an oxazole derivative, an aromatic ketone derivative with replacement of an alkylamino group, or a dialkylaminobenzoic acid ester derivative.

Examples of pyrazoline derivatives include 1-phenyl-3-(4-tert-butyl-styryl)-5-(4-tert-butyl-phenyl)-pyrazoline, 1-(4-(benzooxazol-2-yl)phenyl)-3-(4-tert-butyl-styryl)-5-(4-tert-butyl-phenyl)-pyrazoline, 1-phenyl-3-(4-biphenyl)-5-(4-tert-butyl-phenyl)-pyrazoline, 1-phenyl-3-(4-biphenyl)-5-(4-tert-octyl-phenyl)-pyrazoline, 1-phenyl-3-(4-isopropylstyryl)-5-(4-isopropylphenyl)-pyrazoline, 1-phenyl-3-(4-methoxystyryl)-5-(4-methoxyphenyl)-pyrazoline, I-phenyl-3-(3,5-dimethoxvstyryl)-5-(3,5-dimethoxyphenyl)-pyrazoline, 1-phenyl-3-(3,4-dimethoxystyryl)-5-(3,4-dimethoxyphenyl)-pyrazoline, 1-phenyl-3-(2,6-dimethoxystyryl)-5-(2,6-dimethoxyphenyl)-pyrazoline, 1-phenyl-3-(2,5-dimethoxystyrvl)-5-(2,5-dimethoxyphenyl)-pyrazoline, 1-phenyl-3-(2,3-dimethoxystvryl)-5-(2,3-dimethoxyphenyl)-pyrazoline and 1-phenyl-3-(2,4-dimethoxystyryl)-5-(2,4-dimethoxvphenyl)-pyrazoline.

Examples of anthracene derivatives include 9,10-dimethoxyanthracene, 9,10-diethoxyanthracene, 2-ethyl-9,10-dimethoxyanthracene, 2-ethyl-9,10-diethoxyanthracene, 9,10-dipropoxyanthracene, 9,10-dibutoxyanthracene, 9,10-dipentoxyanthracene, 9,10-dibutoxyanthracene, 2-ethyl-9,10-dibutoxyanthracene, 9-bromo-10-phenylanthracene, 9-chloro-10-phenylanthracene, 9-bromo-10-(2-naphthyl)anthracene, 9-bromo-10-(1-naphthyl)anthracene, 9-(2-biphenylyl)-10-bromoanthracene, 9-(4-biphenylyl)-10-bromoanthracene, 9-bromo-10-(9-phenantholyl)anthracene, 2-bromoanthracene, 9-bromoanthracene, 2-chloroanthracene, 9,10-dibromoanthracene and 9-(3-bromophenyl)-10-phenylanthracene.

Examples of oxazole derivatives include 5-tert-butyl-2-[5-(5-tert-butyl-1,3-benzoxazol-2-yl)thiophen-2-yl]-1,3-benzoxazole and 2-[4-(1,3-benzoxazol-2-yl)naphthalen-1-yl]-1,3-benzoxazole.

Examples of N-aryl-α-amino acid derivatives include N-phenylglycine, N-methyl-N-phenylglycine, N-ethyl-N-phenylglycine, N-(n-propyl)-N-phenylglycine, N-(n-butyl)-N-phenylglycine, N-(2-methoxyethyl)-N-phenylglycine, N-methyl-N-phenylalanine, N-ethyl-N-phenylalanine, N-(n-propyl)-N-phenylalanine, N-(n-butyl)-N-phenylalanine, N-methyl-N-phenylvaline, N-methyl-N-phenylleucine, N-methyl-N-(p-tolyl)glycine, N-ethyl-N-(p-tolyl)glycine, N-(n-propyl)-N-(p-tolyl)glycine, N-(n-butyl)-N-(p-tolyl)glycine, N-methyl-N-(p-chlorophenyl)glycine, N-ethyl-N-(p-chlorophenyl)glycine, N-(n-propyl)-N-(p-chlorophenyl)glycine, N-methyl-N-(p-bromophenyl)glycine, N-ethyl-N-(p-bromophenyl)glycine, N-(n-butyl)-N-(p-bromophenyl)glycine, N, N′-diphenylglvcine, N-methyl-N-(p-iodophenyl)glycine, N-(p-bromophenyl)glycine, N-(p-chlorophenyl)glycine and N-(p-chlorophenyl)glycine. Particularly preferred is N-phenylglycine which has a high sensitizing effect.

Aromatic ketone derivatives with replacement of alkylanino groups include benzophenone derivatives, specific examples of which are alkylbenzophenone compounds such as benzophenone, 2-methylbenzophenone, 3-methylbenzophenone or 4-methylbenzophenone, benzophenone compounds with halogen atoms such as 2-chlorobenzophenone, 4-chlorobenzophenone or 4-bromobenzophenone, benzophenone compounds with replacement of carboxy groups or alkoxycarbonyl groups, such as 2-carboxybenzophenone, 2-ethoxycarbonylbenzophenone, benzophenonetetracarboxylic acid or their tetramethyl esters, bis(dialkylamino)benzophenone compounds such as 4,4′-bis(dimethylamino)benzophenone, 4,4′-bis(dicyclohexylamino)benzophenone, 4,4′-bis(diethylamino)benzophenone and 4,4′-bis(dihydroxyethylamino)benzophenone (preferably 4,4′-bis(dialkylamino)benzophenone compounds), or 4-methoxv-4′-dimethylaminobenzophenone, 4-methoxybenzophenone or 4,4′-dimethoxybenzophenone. Among these, 4,4′-bis(diethylamino)benzophenone is preferred from the viewpoint of adhesiveness.

The sensitizing agent (C) may be used as a single type alone or a mixture of two or more types. The photosensitive resin composition of the embodiment preferably further includes a benzophenone derivative as the sensitizing agent (C).

The content of the sensitizing agent (C) is preferably 0.01 to 1 part by weight and more preferably 0.1 to 0.5 parts by weight, with respect to 100 parts by weight of the alkali-soluble polymer (A).

### (D) Polymerization Inhibitor

Examples for the polymerization inhibitor (D) include phenol derivatives, hydroquinone derivatives, quinone derivatives, free radical-based polymerization inhibitors, nitrobenzene derivatives and phenothiazine derivatives.

Phenol compounds include p-methoxyphenol, hydroquinone, pyrogallol, tert-butylcatechol, 2,6-di-tert-butyl-p-cresol, 2,2′-methylenebis(4-methyl-6-tert-butylphenol), 2,2′-methylenebis(4-ethyl-6-tert-butylphenol), 2,6-di-tert-butyl-4-methylphenol, 2,5-di-tert-amylhydroquinone, 2,5-di-tert-butylhydroquinone, 2,2′-methylenebis(4-methyl-6-tert-butylphenol), bis(2-hydroxy-3-t-butyl-5-ethylphenyl)methane, triethylene glycol-bis[3-(3-t-butyl-5-methyl-4-hydroxyphenyl)propionate], 1,6-hexanediol-bis[3-(3,5-di-t-butyl-4-hydroxyphenyl)propionate], pentaerythrityl tetrakis[3-(3,5-di-t-butyl-4-hydroxyphenyl)propionate], 2,2-thio-diethylenebis[3-(3,5-di-t-butyl-4-hydroxyphenyl)propionate], octadecyl-3-(3,5-di-t-butyl-4-hydroxyphenyl)propionate. N. N′-hexamethylenebis(3,5-di-t-butyl-4-hydroxy-hydrocinnamamide), 3,5-di-t-butyl-4-hydroxybenzyl phosphonate-diethyl ester, 1,3,5-trimethyl-2,4,6-tris(3,5-di-t-butyl-4-hydroxybenzyl)benzene, tris-(3,5-di-t-butyl-4-hydroxybenzyl)-isocyanurate, 4,4′-thiobis(6-tert-butyl-m-cresol), 4,4′-butylidenebis(3-methyl-6-tert-butylphenol), 1,1,3-tris(2-methyl-4-hydroxy-5-tert-butylphenyl)butane, styrenated phenol (for example, ANTAGE SP by Kawaguchi Chemical Industry Co., Ltd.), tribenzylphenol (for example, TBP by Kawaguchi Chemical Industry Co., Ltd., phenol with 1 to 3 benzyl groups), and biphenols.

Examples of hydroquinone compounds include hydroquinone, methylhydroquinone, 2-tert-butylhydroquinone, 2,5-di-tert-butylhydroquinone and 2,6-di-tert-butylhydroquinone.

Examples of quinone compounds include tert-butylbenzoquinone, 2,6-di-tert-butyl-1,4-benzoquinone and 2,5-di-tert-butyl-1,4-benzoquinone.

Examples of free radical-based polymerization inhibitors include nitroso compounds such as p-nitrosophenol, nitrosobenzene, N-nitrosodiphenylamine, isononyl nitrite, N-nitrosocyclohexylhydroxylamine. N-nitrosophenylhydroxylamine and N,N′-dinitrosophenylenediamine, as well as their salts; and hindered amine compounds such as 2,2,6,6-tetramethylpiperidine-1-oxyl, 4-hydroxy-2,2,6,6-tetramethylpiperidine-1-oxyl, 4-hydroxy-2,2,6,6-tetramethyl-1-hydroxypiperidine, 4-oxo-2,2,6,6-tetramethylpiperidine-1-oxyl and 4-oxo-2,2,6,6-tetramethyl-1-oxypiperidine.

Examples of nitrobenzene compounds include nitrobenzene and 4-nitrotoluene.

Phenothiazine compounds include phenothiazine and 2-methoxyphenothiazine.

The polymerization inhibitor (D) preferably includes a phenol derivative. Including a phenol derivative will result in highly excellent adhesiveness and resolution.

The polymerization inhibitor (D) is preferably a phenol derivative from the viewpoint of highly excellent adhesiveness and resolution, and from the same viewpoint, p-methoxyphenol, 2,6-di-tert-butyl-p-cresol, triethylene glycol-bis[3-(3-t-butyl-5-methyl-4-hydroxyphenyl)propionate, 4,4′-butylidenebis(3-methyl-6-tert-butylphenol), catechol, tert-butylcatechol, 2,5-di-tert-butylhydroquinone and biphenol are more preferred. From the same viewpoint, 2,6-di-tert-butyl-p-cresol is preferred as a phenol derivative.

The proportion of polymerization inhibitor (D) with respect to the total solid weight of the photosensitive resin composition is preferably 0.001 weight % to 10 weight %. From the viewpoint of highly excellent adhesiveness and resolution, the proportion is preferably 0.001 weight % or greater, more preferably 0.005 weight % or greater, even more preferably 0.01 weight % or greater, yet more preferably 0.05 weight % or greater and especially preferably 0.1 weight % or greater. From the viewpoint of lower reduction in sensitivity and increased resolution, on the other hand, the proportion is preferably 10 weight % or lower, more preferably 8 weight % or lower, even more preferably 5 weight % or lower, yet more preferably 3 weight % or lower, especially preferably 2 weight % or lower and most preferably 1.5 weight % or lower.

For this embodiment, the photosensitive resin composition layer may also comprise a coloring dye which emits color upon photoirradiation. Examples of known coloring dyes include combinations of leuco dyes and halogenated compounds. Examples of leuco dyes include tris(4-dimethylamino-2-methylphenyl)methane [leuco crystal violet] and tris(4-dimethylamino-2-methylphenyl)methane [leuco malachite green]. Examples of halogenated compounds include amyl bromide, isoamyl bromide, isobutylene bromide, ethylene bromide, diphenylmethyl bromide, benzal bromide, methylene bromide, tribromomethylphenylsulfone, carbon tetrabromide, tris(2,3-dibromopropyl)phosphate, trichloroacetamide, amyl iodide, isobutyl iodide, 1,1,1-trichloro-2,2-bis(p-chlorophenyl)ethane and hexachloroethane.

According to this embodiment, the photosensitive resin composition layer may further comprise additives such as a plasticizer, as necessary. Examples of additives include phthalic acid esters such as diethyl phthalate, amide o-toluenesulfonate, amide p-toluenesulfonate, tributyl citrate, triethyl citrate, triethyl acetylcitrate, tri-n-propyl acetylcitrate, tri-n-butyl acetylcitrate, polypropylene glycol, polyethylene glycol, polyethyleneglycol alkyl ethers and polypropyleneglycol alkyl ethers.

The thickness of the photosensitive resin composition layer is preferably 3 to 100 μm, with a more preferred upper limit being 50 μm. If the photosensitive resin layer thickness approaches 3 μm it will have improved resolution, and if it approaches 100 μm the film strength will be increased, and the range is therefore selected as appropriate according to the purpose of use.

### <Protective Film>

The photosensitive element of the embodiment may also be provided with a protective film in addition to the support film and photosensitive resin composition layer.

A protective film functions as a cover, being laminated on the photosensitive resin composition layer side of the laminate of the support film and photosensitive resin composition layer.

Since the adhesive force between the photosensitive resin composition layer and the protective film is sufficiently smaller than the adhesive force between the photosensitive resin composition layer and the support film, the protective film can be easily stripped from the photosensitive resin composition layer. It is preferred to use a polyethylene film, polypropylene film or stretched polypropylene film, for example, as the protective film.

A layer to be stripped may also be provided on the surface of the protective film.

The protective film thickness is preferably 10 to 100 μm and more preferably 10 to 50 μm. Examples of protective films include EM-501, E-200, E-201F, FG-201 and MA-411 by Oji F-Tex Co., Ltd., KW37, 2578, 2548, 2500 and YMI7S by Toray Co., Ltd., and GF-18, GF-818 and GF-858 by Tamapoly Co., Ltd.

### [Photosensitive Element Roll]

The photosensitive element described above may also be used as a photosensitive element roll comprising a long photosensitive element wound up on a winding core.

### [Resist Pattern Forming Method]

A resist pattern forming method using the photosensitive element of the embodiment preferably includes the following steps in order:
a lamination step in which the photosensitive element is laminated on a substrate;
an exposure step in which the photosensitive resin composition layer of the photosensitive element is exposed; and
a developing step in which the unexposed section of the photosensitive resin composition layer is developed and removed.

Specifically, after the protective film has been stripped from the photosensitive element in the lamination step, the photosensitive resin composition layer is thermocompression bonded to the surface of the support (such as a substrate) using a laminator, for lamination either once or several times. The material of the substrate may be, for example, copper, stainless steel (SUS), glass or indium tin oxide (ITO). The heating temperature during lamination will generally be 40° C. to 160° C. During thermocompression bonding, a two-stage laminator comprising a double roll may be used, or the laminate of the substrate and the photosensitive resin composition layer may be repeatedly passed through rolls several times.

Next, in the exposure step, an exposure device is used for active light exposure of the photosensitive resin composition layer. The exposure may optionally be carried out after stripping the support. When the exposure is performed through a photomask, the exposure dose is set by the light source illuminance and exposure time, and it may be measured using an illuminometer. Direct imaging exposure may also be carried out in the exposure step. For direct imaging exposure, the substrate is exposed from above with a direct writing apparatus, without using a photomask. The light source used may be a semiconductor laser or ultrahigh pressure mercury lamp with a wavelength of 350 nm to 410 nm. When the drawing pattern is controlled by a computer, the exposure dose is determined by the illuminance of the exposure light source and the traveling speed of the substrate.

The photoirradiation method used in the exposure step is preferably at least one type of method selected from among projection printing, proximity exposure, contact exposure, direct imaging exposure and electron beam direct writing methods, and it is more preferably a projection printing method.

A heating step may also be carried out between the exposure step and the developing step. The heating temperature is preferably about 30° C. to about 200° C., more preferably 30° C. to 150° C. and even more preferably 40° C. to 120° C. Carrying out a heating step can further improve the resolution and adhesiveness. The means used for heating may be a heating furnace, thermostatic bath, hot plate, hot air drier, infrared dryer, hot roll or the like, based on a hot air, infrared ray or far-infrared ray system.

The time elapsed from the exposure step until the heating step, and more specifically the time elapsed from the point at which exposure is stopped until heating is initiated, is preferably to 600 seconds and more preferably 20 to 300 seconds. The time elapsed from the start of heating until heating is stopped is preferably 1 to 120 seconds and more preferably 5 to 60 seconds.

In the developing step, the unexposed sections or exposed sections of the exposed photosensitive resin composition layer are removed with a developing solution, using a developing apparatus. When the support film is present on the photosensitive resin composition layer after exposure, it is removed. A developing solution comprising an aqueous alkali solution is then used to develop and remove the unexposed sections or exposed sections, to obtain a resist image.

The aqueous alkali solution is preferably an aqueous solution of Na₂CO₃, K₂CO₃, or the like. The aqueous alkali solution is selected to match the properties of the photosensitive resin composition layer, but generally a Na₂CO₃ aqueous solution at a concentration of 0.2 weight % to 2 weight % is used. A small amount of a surfactant, an antifoaming agent or an organic solvent to promote development may also be mixed with the aqueous alkali solution. The temperature of the developing solution in the developing step is preferably kept constant in the range of 20° C. to 40° C.

A resist pattern is obtained by the steps described above, and if desired a heating step may also be carried out at 60° C. to 300° C. By carrying out such a heating step it is possible to increase the chemical resistance of the resist pattern. A heating furnace of a type using hot air, infrared rays or far-infrared rays may be used in the heating step.

By using the photosensitive element of the embodiment, foaming of the developing solution during development is satisfactorily reduced, and notably, elimination of foam after the developing device has stopped is satisfactory.

In order to obtain a conductor pattern, a conductor pattern forming step may also be carried out, in which the resist pattern-formed substrate is subjected to etching or plating after the developing step or heating step.

The method for producing a conductor pattern is carried out, for example, by forming a resist pattern on a metal sheet or metal film-insulated sheet as the substrate, by the resist pattern forming method described above, and then subjecting it to a conductor pattern forming step. In the conductor pattern forming step, a conductor pattern is formed on the substrate surface (for example, a copper surface) that has been exposed by development, using a known etching method or plating method.

After a conductor pattern has been produced by the method for producing a conductor pattern, a stripping step may then be carried out in which the resist pattern is stripped from the substrate using an aqueous solution with stronger alkalinity than the developing solution, to obtain a circuit board with the desired wiring pattern (for example, a printed circuit board).

The aqueous alkali solution for stripping (hereunder also referred to as “stripping solution”) is not particularly restricted, but generally an aqueous solution of NaOH or KOH at a concentration of 2 weight % to 5 weight %, or an organic amine-based stripping solution, may be used. A small amount of a water-soluble solvent may also be added to the stripping solution. Examples of water-soluble solvents include alcohols. The temperature of the stripping solution in the stripping step is preferably in the range of 40° C. to 70° C.

According to the embodiment, the photosensitive element may be utilized for production of a printed circuit board; for production of an IC chip mounting lead frame; for metal foil precision working such as metal mask production; for production of packages such as ball grid arrays (BGA) and chip size packages (CSP); for production of tape boards such as chip-on-film (COF) and tape-automated bonding (TAB); for production of semiconductor bumps; and for production of flat panel display barriers for ITO electrodes, address electrodes and electromagnetic shields.

The values of the parameters described above are measured by the measuring methods described in the following Examples, unless otherwise specified.

### EXAMPLES

The present embodiment will now be explained in greater detail by Examples and Comparative Examples. However, the embodiment is not limited to the Examples so long as the gist thereof is maintained. The physical properties in the Examples were measured by the following methods.

### [Fabrication of Evaluation Samples]

The evaluation samples were fabricated in the following manner.

### <Fabrication of Photosensitive Elements>

### Examples 1 to 28 and Comparative Examples 1 to 5

The components listed in Table 1 to Table 3 (where the numerical values for the components indicate the added parts by solid weight) and methyl ethyl ketone measured out to 60% solid concentration, were thoroughly stirred and mixed to obtain photosensitive resin composition solutions. Tables 4 to 7 show the details for the components listed in Tables 1 to 3.

Using a 16 μm-thick polyethylene terephthalate film (QS71 by Toray Co., Ltd.) as the support film, its surface was uniformly coated with the respective solutions using a bar coater and dried for 2 minutes and 30 seconds in a dryer at 95° C. to form a photosensitive resin composition layer. The dry thickness of the photosensitive resin composition layer was 25 μm.

Next, a 19 μm-thick polyethylene film (GF-18, by Tamapoly Co., Ltd.) was attached as a protective film to the surface of the photosensitive resin composition layer on the side without the laminated polyethylene terephthalate film, to obtain a photosensitive resin element.

### <Substrate Surface Conditioning>

As an evaluation substrate for image quality, the surface of a 0.4 mm-thick copper-clad laminate with an 18 μm rolled copper foil layer was rinsed with a 10 weight % H₂SO₄ aqueous solution.

### <Lamination>

The polyethylene film (protective film) of the photosensitive element was stripped while using a hot roll laminator (AL-700 by Asahi Kasei K. K.) for lamination of the photosensitive resin laminate onto the copper-clad laminate preheated to 50° C., at a roll temperature of 105° C. The air pressure was 0.35 MPa and the laminating speed was 1.5 m/min.

### <Exposure>

An evaluation substrate two (2) hours after lamination was exposed through a glass mask using a projection exposure system (UX-44101SM by Ushio Inc.). The exposure was carried out at the L (line)/S (space)=10 μm/10 μm locations of the mask, with an exposure dose for a cured resist pattern line width of 10 μm after development.

### <Heating>

The evaluation substrate one (1) minute after exposure was heated for 30 seconds using an airflow-controlled constant temperature oven (DKM600 by Yamato Scientific Co., Ltd.) set to 60° C.

### <Development>

After stripping the polyethylene terephthalate film (support film), an alkali developing machine (dry film developing machine, by Fuji Kiko Co. Ltd.) was used for spraying of a 1 weight % Na₂CO₃ aqueous solution at 30° C. for a prescribed period of time, for development. The development spraying time was set to be twice the minimum developing time, and the rinse spraying time after development was set to be twice the minimum developing time. The shortest time required to completely dissolve the unexposed sections of the photosensitive resin layer was recorded as the minimum developing time.

### [Evaluation]

Each fabricated sample was evaluated in the following manner in regard to developability, resolution, flexibility and foam elimination.

### <Developability>

After laminating the photosensitive element onto the substrate, the minimum development time after elapse of 15 minutes was measured and evaluated on the following scale.
Excellent: Minimum development time of <20 seconds
Good: Minimum development time of 20 seconds and <25 seconds
Acceptable: Minimum development time of ≥25 seconds and <30 seconds
Unacceptable: Minimum development time of 30 seconds

### <Resolution>

The L/S=1/1 pattern section of the obtained substrate was observed with a microscope and evaluated on the following scale.
Excellent: Minimum formable section of ≤6 μm/6 μm
Good: Minimum formable section of ≤7 μm/7 μm
Acceptable: Minimum formable section of ≤8 μm/8 μm
Unacceptable: Minimum formable section of ≤9 m/9 m

### <Flexibility>

### (Fabrication of Evaluation Sample)

The polyethylene film (protective film) of the photosensitive element was stripped while using a hot roll laminator (AL-700 by Asahi Kasei K. K.) for lamination of the photosensitive resin laminate onto a copper-clad laminate for a polyimide film substrate flexible printed circuit (NIKAFLEX F-30 VC1 25RC11(H) by Nikkan Industries Co., Ltd.) cut out to 7 cm×20 cm, at a roll temperature of 105° C. The air pressure was 0.35 MPa and the laminating speed was 1.5 m/min. Exposure was carried out using a projection exposure system (UX-2203SM by Ushio Inc.), without a glass mask. The evaluation substrate 1 minute after exposure was heated for 30 seconds using an airflow-controlled constant temperature oven (DKM600 by Yamato Scientific Co., Ltd.) set to 60° C., and then developed for twice the minimum developing time to obtain an evaluation sample. The prepared sample was humidified for 1 day at 23° C., 50% RH.

### (Evaluation Method)

The humidified evaluation sample was tested according to JIS K5600-5-1 (flex resistance (cylindrical mandrel)) and ISO1519, and evaluated on the following scale.
Excellent: No bending, cracking or peeling with 8 mmφ mandrel
Good: No bending, cracking or peeling with 10 mmφ mandrel
Acceptable: No bending, cracking or peeling with 12 mmφ mandrel
Unacceptable: No bending, cracking or peeling with 16 mmφ mandrel

### <Foam Elimination>

### (Fabrication of Evaluation Samples)

The polyethylene terephthalate film (support film) and polyethylene film (protective film) of the photosensitive element were stripped, and 20 g of the photosensitive resin composition was measured off. The photosensitive resin composition was then poured into 1 L of 1% aqueous sodium carbonate and stirred at 30° C. for 2 hours to obtain an evaluation sample.

### (Evaluation Method)

The developing solution with the dissolved photosensitive resin composition was foamed under the following conditions according to JIS K 2518:2017.
Sample amount: 190 mL
Cylinder: L480, φ65 mm, scale: 0 to 1,000 mL, scale interval: 10 mL
Air flow rate: 94 mL/min
Test time: 5 minutes

The amount of foam was evaluated as the degree of foam elimination after standing for 1 minute, according to the following scale.

Excellent: Foam height: <10 mL
Good: Foam height: ≥10 mL and <25 mL
Acceptable: Foam height: ≥25 mL and <50 mL
Unacceptable: Foam height: ≥50 mL

The evaluation results for the samples of Examples 1 to 12 are shown in Table 1, the evaluation results for the samples of Examples 13 to 23 are shown in Table 2, and the evaluation results for the samples of Examples 24 to 28 and Comparative Examples 1 to 5 are shown in Table 3. Tables 4 to 7 show the details for the components listed in Tables 1 to 3.

TABLE 1-1

| Compound | | | Example 1 | Example 2 | Example 3 | Example 4 | Example 5 | Example 6 |
|---|---|---|---|---|---|---|---|---|
| Alkali-soluble | | A-1 | | | | | | |
| polymer (A) | | A-2 | 40 | | | | | 40 |
| | | A-3 | | 40 | | | | |
| | | A-4 | | | 40 | | | |
| | | A-5 | | | | 40 | | |
| | | A-6 | | | | | 40 | |
| | | A-7 | | 15 | | 15 | | 15 |
| | | A-8 | 15 | | 15 | | 15 | |
| Compound with | B1 | B-1 | | | | | | 3 |
| ethylenically | | B-2 | | | | | | |
| unsaturated | | B-3 | | | 3 | | | |
| double bond | | B-4 | 3 | | | 3 | | |
| (B) | | B-5 | | 3 | | | 3 | |
| | | B-6 | | | | | | |
| | | B-7 | | | | | | |
| | | B-8 | | | | | | |
| | | B-9 | | | | | | |
| | | B-10 | | | | | | |
| | B-11 | | | | | | | |
| | B-12 | | | | | | | |
| | B2 | B-13 | | | | | | |
| | | B-14 | 7 | 7 | 5 | 5 | 5 | |
| | | B-15 | 5 | 5 | 7 | 7 | 7 | |
| | | B-16 | | | | | | 7 |
| | | B-17 | | | | | | |
| | B3 | B-18 | | | | | | 5 |
| | | B-19 | | | | | | |
| | | B-20 | | | | | | |
| | | B-21 | | | | | | |
| | | B-22 | | | | | | |
| | B4 | B-23 | 15 | | | 10 | | |
| | | B-24 | | 10 | | | | 10 |

| | | | | | | | |
|---|---|---|---|---|---|---|---|
| | B-25 | 10 | 15 | 15 | 15 | 10 | 15 |
| | B-26 | | | 10 | | | |
| Sensitizing | C-1 | 0.07 | 0.07 | 0.07 | 0.07 | 0.07 | 0.07 |
| agent (C) | C-2 | | | | | | |
| Polymerization | 2,6-di-tert- | 0.15 | 0.15 | 0.15 | 0.15 | 0.15 | 0.15 |
| inhibitor (D) | butyl-para- | | | | | | |
| | cresol | | | | | | |

| | | | | | | |
|---|---|---|---|---|---|---|
| 2-(o-Chlorophenyl)-4,5- | 3 | 3 | 3 | 3 | 3 | 3 |
| diphenylimidazole dimer | | | | | | |
| Diamond Green | 0.16 | 0.16 | 0.16 | 0.16 | 0.16 | 0.16 |
| Leuco crystal violet | 0.4 | 0.4 | 0.4 | 0.4 | 0.4 | 0.4 |
| Carboxybenzotriazole | 0.02 | 0.02 | 0.02 | 0.02 | 0.02 | 0.02 |
| Aluminum salt with | 0.008 | 0.008 | 0.008 | 0.008 | 0.008 | 0.008 |
| addition of 3 mol | | | | | | |
| nitrosophenylhydroxylamine | | | | | | |

TABLE 1-2

| | | Example 1 | Example 2 | Example 3 | Example 4 | Example 5 | Example 6 |
|---|---|---|---|---|---|---|---|
| Total | | 98.808 | 98.808 | 98.808 | 98.808 | 83.808 | 98.808 |
| Evaluation | Developability | Acceptable | Good | Excellent | Excellent | Acceptable | Acceptable |
| | Resolution | Good | Good | Excellent | Good | Good | Excellent |
| | Flexibility | Excellent | Excellent | Good | Good | Excellent | Excellent |
| | Foam elimination | Excellent | Excellent | Good | Excellent | Excellent | Acceptable |

TABLE 1-3

| Compound | | | Example 7 | Example 8 | Example 9 | Example 10 | Example 11 | Example 12 |
|---|---|---|---|---|---|---|---|---|
| Alkali-soluble | | A-1 | | | | | | |
| polymer (A) | | A-2 | | | | 40 | | |
| | | A-3 | 40 | | | | | |
| | | A-4 | | 40 | | | 40 | |
| | | A-5 | | | | | | |
| | | A-6 | | | 40 | | | 40 |
| | | A-7 | | 15 | | 15 | 15 | |
| | | A-8 | 15 | | 15 | | | 15 |
| Compound with | B1 | B-1 | | | | | | |
| ethylenically | | B-2 | 3 | | | | | |
| unsaturated | | B-3 | | | | | | |
| double bond | | B-4 | | | | | | |
| (B) | | B-5 | | | | | | |
| | | B-6 | | 3 | | | | |
| | | B-7 | | | 3 | | | |
| | | B-8 | | | | 3 | | |
| | | B-9 | | | | | 3 | |
| | | B-10 | | | | | | 3 |
| | B-11 | | | | | | | |
| | B-12 | | | | | | | |
| | B2 | B-13 | | | | | | |
| | | B-14 | | | 5 | 5 | | |
| | | B-15 | | | | | 5 | 5 |
| | | B-16 | 7 | 7 | | | | |
| | | B-17 | | | 7 | 7 | | |
| | B3 | B-18 | 5 | 5 | | | 7 | 7 |
| | | B-19 | | | | | | |
| | | B-20 | | | | | | |
| | | B-21 | | | | | | |
| | | B-22 | | | | | | |
| | B4 | B-23 | | 10 | | | 10 | |
| | | B-24 | | | | 10 | | |

| | | | | | | | |
|---|---|---|---|---|---|---|---|
| | B-25 | 15 | 15 | 10 | 15 | 15 | 10 |
| | B-26 | 10 | | 15 | | | |
| Sensitizing | C-1 | 0.07 | 0.07 | 0.07 | 0.07 | 0.07 | 0.07 |
| agent (C) | C-2 | | | | | | |
| Polymerization | 2,6-di-tert- | 0.15 | 0.15 | 0.15 | 0.15 | 0.15 | 0.15 |
| inhibitor (D) | butyl-para- | | | | | | |
| | cresol | | | | | | |

| | | | | | | |
|---|---|---|---|---|---|---|
| 2-(o-Chlorophenyl)-4,5- | 3 | 3 | 3 | 3 | 3 | 3 |
| diphenylimidazole dimer | | | | | | |
| Diamond Green | 0.16 | 0.16 | 0.16 | 0.16 | 0.16 | 0.16 |
| Leuco crystal violet | 0.4 | 0.4 | 0.4 | 0.4 | 0.4 | 0.4 |
| Carboxybenzotriazole | 0.02 | 0.02 | 0.02 | 0.02 | 0.02 | 0.02 |
| Aluminum salt with | 0.008 | 0.008 | 0.008 | 0.008 | 0.008 | 0.008 |
| addition of 3 mol | | | | | | |
| nitrosophenylhydroxylamine | | | | | | |

TABLE 1-4

| | | Example 7 | Example 8 | Example 9 | Example 10 | Example 11 | Example 12 |
|---|---|---|---|---|---|---|---|
| Total | | 98.808 | 98.808 | 98.808 | 98.808 | 98.808 | 83.808 |
| Evaluation | Developability | Good | Excellent | Acceptable | Acceptable | Excellent | Acceptable |
| | Resolution | Excellent | Excellent | Acceptable | Acceptable | Acceptable | Acceptable |
| | Flexibility | Excellent | Excellent | Excellent | Excellent | Excellent | Excellent |
| | Foam elimination | Acceptable | Good | Good | Acceptable | Good | Acceptable |

TABLE 2-1

| Compound | | | Example 13 | Example 14 | Example 15 | Example 16 | Example 17 | Example 18 |
|---|---|---|---|---|---|---|---|---|
| Alkali-soluble | | A-1 | | | | | | |
| polymer (A) | | A-2 | | | | 40 | | |
| | | A-3 | 40 | | | | 40 | |
| | | A-4 | | 40 | | | | 40 |
| | | A-5 | | | | | | |
| | | A-6 | | | 40 | | | |
| | | A-7 | | 15 | | 15 | | 15 |
| | | A-8 | 15 | | 15 | | 15 | |
| Compound with | B1 | B-1 | | | | | | |
| ethylenically | | B-2 | | | | | | |
| unsaturated | | B-3 | 1 | 5 | 9 | | | |
| double bond | | B-4 | | | | 1 | 5 | 9 |
| (B) | | B-5 | | | | | | |
| | | B-6 | | | | | | |
| | | B-7 | | | | | | |
| | | B-8 | | | | | | |
| | | B-9 | | | | | | |
| | | B-10 | | | | | | |
| | B-11 | | | | | | | |
| | B-12 | | | | | | | |
| | B2 | B-13 | | | | | | |
| | | B-14 | | | | | | |
| | | B-15 | 5 | 5 | 5 | | | |
| | | B-16 | | | | | | |
| | | B-17 | | | | | | |
| | B3 | B-18 | | | | | | |
| | | B-19 | 7 | 7 | 7 | | | |
| | | B-20 | | | | 7 | 7 | 7 |
| | | B-21 | | | | 5 | 5 | 5 |
| | | B-22 | | | | | | |
| | B4 | B-23 | | 10 | | | | 10 |
| | | B-24 | | | 15 | 10 | | |

| | | | | | | | |
|---|---|---|---|---|---|---|---|
| | B-25 | 15 | 15 | 10 | 15 | 15 | 15 |
| | B-26 | 10 | | | | 10 | |
| Sensitizing | C-1 | 0.07 | 0.07 | 0.07 | 0.07 | 0.07 | 0.07 |
| agent (C) | C-2 | | | | | | |
| Polymerization | 2,6-di-tert- | 0.15 | 0.15 | 0.15 | 0.15 | 0.15 | 0.15 |
| inhibitor (D) | Butyl-para- | | | | | | |
| | cresol | | | | | | |

| | | | | | | |
|---|---|---|---|---|---|---|
| 2-(o-Chlorophenyl)-4,5- | 3 | 3 | 3 | 3 | 3 | 3 |
| diphenylimidazole dimer | | | | | | |
| Diamond Green | 0.16 | 0.16 | 0.16 | 0.16 | 0.16 | 0.16 |
| Leuco crystal violet | 0.4 | 0.4 | 0.4 | 0.4 | 0.4 | 0.4 |
| Carboxybenzotriazole | 0.02 | 0.02 | 0.02 | 0.02 | 0.02 | 0.02 |
| Aluminum salt with | 0.008 | 0.008 | 0.008 | 0.008 | 0.008 | 0.008 |
| addition of 3 mol | | | | | | |
| nitrosophenylhydroxylamine | | | | | | |

TABLE 2-2

| | | Example 13 | Example 14 | Example 15 | Example 16 | Example 17 | Example 18 |
|---|---|---|---|---|---|---|---|
| Total | | 96.808 | 100.808 | 104.808 | 96.808 | 100.808 | 104.808 |
| Evaluation | Developability | Good | Excellent | Acceptable | Acceptable | Good | Excellent |
| | Resolution | Excellent | Excellent | Excellent | Good | Good | Good |
| | Flexibility | Excellent | Excellent | Excellent | Excellent | Excellent | Excellent |
| | Foam elimination | Good | Good | Good | Excellent | Excellent | Excellent |

TABLE 2-3

| Compound | | | Example 19 | Example 20 | Example 21 | Example 22 | Example 23 |
|---|---|---|---|---|---|---|---|
| Alkali-soluble | | A-1 | | | | | |
| polymer (A) | | A-2 | | 40 | | | |
| | | A-3 | | | 40 | | |
| | | A-4 | | | | 40 | |
| | | A-5 | | | | | |
| | | A-6 | 40 | | | | 40 |
| | | A-7 | | 15 | | 15 | |
| | | A-8 | 15 | | 15 | | 15 |
| Compound with | B1 | B-1 | | | | | |
| ethylenically | | B-2 | | | | | |
| unsaturated | | B-3 | 3 | | | 3 | |
| double bond | | B-4 | | 3 | | | 3 |
| (B) | | B-5 | | | 3 | | |
| | | B-6 | | | | | |
| | | B-7 | | | | | |
| | | B-8 | | | | | |
| | | B-9 | | | | | |
| | | B-10 | | | | | |
| | B-11 | | | | | | |
| | B-12 | | | | | | |
| | B2 | B-13 | | | | | |
| | | B-14 | 5 | 5 | 5 | | |
| | | B-15 | | | | 5 | 5 |
| | | B-16 | | | | | |
| | | B-17 | | | | | |
| | B3 | B-18 | | | | | |
| | | B-19 | | | | | |
| | | B-20 | | | | | |
| | | B-21 | 7 | 7 | 7 | | |
| | | B-22 | | | | 7 | 7 |
| | B4 | B-23 | 15 | | | 10 | |
| | | B-24 | | 10 | | | |

| | | | | | | |
|---|---|---|---|---|---|---|
| | B-25 | 10 | 15 | 15 | 15 | 10 |
| | B-26 | | | 10 | | |
| Sensitizing | C-1 | 0.07 | 0.07 | 0.07 | 0.07 | 0.07 |
| agent (C) | C-2 | | | | | |
| Polymerization | 2,6-di-tert- | 0.15 | 0.15 | 0.15 | 0.15 | 0.15 |
| inhibitor (D) | Butyl-para- | | | | | |
| | cresol | | | | | |

| | | | | | |
|---|---|---|---|---|---|
| 2-(o-Chlorophenyl)-4,5- | 3 | 3 | 3 | 3 | 3 |
| diphenylimidazole dimer | | | | | |
| Diamond Green | 0.16 | 0.16 | 0.16 | 0.16 | 0.16 |
| Leuco crystal violet | 0.4 | 0.4 | 0.4 | 0.4 | 0.4 |
| Carboxybenzotriazole | 0.02 | 0.02 | 0.02 | 0.02 | 0.02 |
| Aluminum salt with | 0.008 | 0.008 | 0.008 | 0.008 | 0.008 |
| addition of 3 mol | | | | | |
| nitrosophenylhydroxylamine | | | | | |

TABLE 2-4

| | | Example 19 | Example 20 | Example 21 | Example 22 | Example 23 |
|---|---|---|---|---|---|---|
| Total | | 98.808 | 98.808 | 98.808 | 98.808 | 83.808 |
| Evaluation | Developability | Acceptable | Acceptable | Good | Excellent | Acceptable |
| | Resolution | Excellent | Good | Good | Excellent | Good |
| | Flexibility | Excellent | Excellent | Excellent | Excellent | Excellent |
| | Foam elimination | Good | Excellent | Excellent | Good | Excellent |

TABLE 3-1

| Compound | | | Example 24 | Example 25 | Example 26 | Example 27 | Example 28 |
|---|---|---|---|---|---|---|---|
| Alkali-soluble | | A-1 | | | | | |
| polymer (A) | | A-2 | 40 | | 40 | | |
| | | A-3 | | 40 | | 40 | |
| | | A-4 | | | | | |
| | | A-5 | | | | | |
| | | A-6 | | | | | 40 |
| | | A-7 | 15 | | 15 | | 15 |
| | | A-8 | | 15 | | 15 | |
| Compound with | B1 | B-1 | | | | | |
| ethylenically | | B-2 | | | | | |
| unsaturated | | B-3 | | 9 | | | |
| double bond | | B-4 | | | | | |
| (B) | | B-5 | 3 | | | | 3 |
| | | B-6 | | | | 3 | |
| | | B-7 | | | | | |
| | | B-8 | | | 3 | | |
| | | B-9 | | | | | |
| | | B-10 | | | | | |
| | B-11 | | | | | | |
| | B-12 | | | | | | |
| | B2 | B-13 | | | | | |
| | | B-14 | | | 5 | | 5 |
| | | B-15 | 5 | 5 | | | 7 |
| | | B-16 | | | | 7 | |
| | | B-17 | | | 7 | | |
| | B3 | B-18 | | | | 5 | |
| | | B-19 | | 7 | | | |
| | | B-20 | | | | | |
| | | B-21 | | | | | |
| | | B-22 | 7 | | | | |
| | B4 | B-23 | | | | 10 | |
| | | B-24 | 10 | 15 | 10 | | |

| | | | | | | |
|---|---|---|---|---|---|---|
| | B-25 | 15 | 10 | 15 | 15 | 10 |
| | B-26 | | | | | |
| Sensitizing | C-1 | 0.07 | 0.07 | | | |
| agent (C) | C-2 | | | 0.3 | 0.3 | 0.3 |
| Polymerization | 2,6-di-tert- | 0.15 | 0.15 | 0.15 | 0.15 | 0.15 |
| inhibitor (D) | Butyl-para- | | | | | |
| | cresol | | | | | |

| | | | | | |
|---|---|---|---|---|---|
| 2-(o-Chlorophenyl)-4,5- | 3 | 3 | 3 | 3 | 3 |
| diphenylimidazole dimer | | | | | |
| Diamond Green | 0.16 | 0.16 | 0.16 | 0.16 | 0.16 |
| Leuco crystal violet | 0.4 | 0.4 | 0.4 | 0.4 | 0.4 |
| Carboxybenzotriazole | 0.02 | 0.02 | 0.02 | 0.02 | 0.02 |
| Aluminum salt with | 0.008 | 0.008 | 0.008 | 0.008 | 0.008 |
| addition of 3 mol | | | | | |
| nitrosophenylhydroxylamine | | | | | |

TABLE 3-2

| | | Example 24 | Example 25 | Example 26 | Example 27 | Example 28 |
|---|---|---|---|---|---|---|
| Total | | 98.808 | 104.808 | 99.038 | 99.038 | 84.038 |
| Evaluation | Developability | Acceptable | Good | Acceptable | Good | Acceptable |
| | Resolution | Good | Excellent | Acceptable | Excellent | Good |
| | Flexibility | Excellent | Excellent | Excellent | Excellent | Excellent |
| | Foam elimination | Excellent | Good | Acceptable | Good | Excellent |

TABLE 3-3

| | | | Comp. | Comp. | Comp. | Comp. | Comp. |
|---|---|---|---|---|---|---|---|
| Compound | | | Example 1 | Example 2 | Example 3 | Example 4 | Example 5 |
| Alkali-soluble | | A-1 | 40 | | | | |
| polymer (A) | | A-2 | | | 40 | | |
| | | A-3 | | 40 | | | 40 |
| | | A-4 | | | | | |
| | | A-5 | | | | | |
| | | A-6 | | | | | |
| | | A-7 | 15 | | 15 | 55 | |
| | | A-8 | | 15 | | | 15 |
| Compound with | B1 | B-1 | | | | | |
| ethylenically | | B-2 | | | | | |
| unsaturated | | B-3 | 3 | | | | |
| double bond | | B-4 | | | | | |
| (B) | | B-5 | | | | 3 | |
| | | B-6 | | | | | |
| | | B-7 | | | | | |
| | | B-8 | | | | | |
| | | B-9 | | | | | |
| | | B-10 | | | | | |
| | B-11 | | | 3 | | | |
| | B-12 | | | | 3 | | |
| | B2 | B-13 | | | | | 3 |
| | | B-14 | 7 | 5 | | 5 | |
| | | B-15 | 5 | | 5 | 7 | |
| | | B-16 | | | | | 7 |
| | | B-17 | | 7 | | | |
| | B3 | B-18 | | | 7 | | 5 |
| | | B-19 | | | | | |
| | | B-20 | | | | | |
| | | B-21 | | | | | |
| | | B-22 | | | | | |
| | B4 | B-23 | 10 | | | | |
| | | B-24 | | | 10 | | |

| | | | | | | |
|---|---|---|---|---|---|---|
| | B-25 | 15 | 15 | 15 | 10 | 10 |
| | B-26 | | 10 | | | |
| Sensitizing | C-1 | 0.07 | 0.07 | 0.07 | | |
| agent (C) | C-2 | | | | 0.3 | 0.3 |
| Polymerization | 2,6-di-tert- | 0.15 | 0.15 | 0.15 | 0.15 | 0.15 |
| inhibitor (D) | Butyl-para- | | | | | |
| | cresol | | | | | |

| | | | | | |
|---|---|---|---|---|---|
| 2-(o-Chlorophenyl)-4,5- | 3 | 3 | 3 | 3 | 3 |
| diphenylimidazole dimer | | | | | |
| Diamond Green | 0.16 | 0.16 | 0.16 | 0.16 | 0.16 |
| Leuco crystal violet | 0.4 | 0.4 | 0.4 | 0.4 | 0.4 |
| Carboxybenzotriazole | 0.02 | 0.02 | 0.02 | 0.02 | 0.02 |
| Aluminum salt with | 0.008 | 0.008 | 0.008 | 0.008 | 0.008 |
| addition of 3 mol | | | | | |
| nitrosophenylhydroxylamine | | | | | |

TABLE 3-4

| | | Comp. | Comp. | Comp. | Comp. | Comp. |
|---|---|---|---|---|---|---|
| | | Example 1 | Example 2 | Example 3 | Example 4 | Example 5 |
| Total | | 98.808 | 98.808 | 98.808 | 84.038 | 84.038 |
| Evaluation | Developability | Unacceptable | Good | Acceptable | Unacceptable | Good |
| | Resolution | Excellent | Unacceptable | Unacceptable | Good | Excellent |
| | Flexibility | Excellent | Excellent | Excellent | Excellent | Excellent |
| | Foam elimination | Good | Unacceptable | Unacceptable | Excellent | Unacceptable |

TABLE 4

| Symbol | Structure | Mw |
|---|---|---|
| A-1 | Methacrylic acid/methyl | 25,000 |
| | methacrylate/styrene = 25/10/65 | |
| A-2 | Methacrylic acid/methyl | 20,000 |
| | methacrylate/styrene = 25/10/65 | |
| A-3 | Methacrylic acid/methyl | 15,000 |
| | methacrylate/styrene = 25/10/65 | |
| A-4 | Methacrylic acid/methyl | 10,000 |
| | methacrylate/styrene = 25/10/65 | |
| A-5 | Methacrylic acid/methyl | 8000 |
| | methacrylate/styrene = 25/10/65 | |
| A-6 | Methacrylic acid/styrene/benzyl | 19,000 |
| | methacrylate = 25/60/15 | |
| A-7 | Methacrylic acid/benzyl | 50,000 |
| | methacrylate = 20/80 | |
| A-8 | Methacrylic acid/2-ethylhexyl | 50,000 |
| | acrylate/styrene/2-hydroxyethyl | |
| | methacrylate = 30/20/40/10 | |
| None | — | 0 |

TABLE 5

| Symbol | Structure | n | m1 + m2 |
|---|---|---|---|
| B-1 | Polypropylene glycol | 1 | 0 |
| | dimethacrylate | | |
| B-2 | Polypropylene glycol | 2 | 0 |
| | dimethacrylate | | |
| B-3 | Polypropylene glycol | 3 | 0 |
| | dimethacrylate | | |
| B-4 | Polypropylene glycol | 7 | 0 |
| | dimethacrylate | | |
| B-5 | Polypropylene glycol | 8 | 0 |
| | dimethacrylate | | |
| B-6 | Polypropylene glycol | 12 | 0 |
| | dimethacrylate | | |
| B-7 | Polypropylene glycol | 15 | 0 |
| | dimethacrylate | | |
| B-8 | Polypropylene glycol | 30 | 0 |
| | dimethacrylate | | |
| B-9 | Polyethylenepolypropylene | 7 | 2 |
| | glycol dimethacrylate | | |
| B-10 | Polyethylenepolypropylene | 9 | 8 |
| | glycol dimethacrylate | | |
| B-11 | Polypropylene glycol | 35 | 0 |
| | dimethacrylate | | |
| B-12 | Polyethylenepolypropylene | 5 | 12 |
| | glycol dimethacrylate | | |
| B-13 | Polyethylene glycol | 0 | 4 |
| | dimethacrylate | | |

TABLE 6

| | | | | | Other |
|---|---|---|---|---|---|
| Symbol | Structure | Central backbone | k | l | substituents |
| B-14 | Dimethacrylate of polytetramethylene glycol | — | 28 | — | None |
| | (tetramethylene glycol repeating units: 28 mol) | | | | |
| B-15 | Trimethacrylate with average 13 mol tetramethylene | Trimethylolpropane | 13 | — | PO3 mol |
| | oxide and average 3 mol of propylene oxide added | | | | |
| | to trimethylolpropane | | | | |
| B-16 | Trimethacrylate with average 8 mol tetramethylene | Trimethylolpropane | 8 | — | None |
| | oxide added to trimethylolpropane | | | | |
| B-17 | Tetramethacrylate with average 20 mol | Pentaerythritol | 20 | — | PO3 mol |
| | tetramethylene oxide and average 3 mol of | | | | |
| | propylene oxide added to pentaerythritol | | | | |
| B-18 | Hexamethacrylate with average 28 mol | Dipentaerythritol | 28 | — | None |
| | tetramethylene oxide added to dipentaerythritol | | | | |
| B-19 | Tetramethacrylate with average 15 mol caprolactone | Trimethylolpropane | — | 15 | None |
| | added to trimethylolpropane | | | | |
| B-20 | Tetramethacrylate with average 15 mol caprolactone | Pentaerythritol | — | 15 | None |
| | added to pentaerythritol | | | | |
| B-21 | Tetramethacrylate with average 15 mol caprolactone | Pentaerythritol | — | 25 | None |
| | added to pentaerythritol | | | | |
| B-22 | Hexamethacrylate with average 25 mol caprolactone | Dipentaerythritol | — | 25 | None |
| | added to dipentaerythritol | | | | |
| B-23 | Dimethacrylate of polyethylene glycol, with average | Hydrogenated | — | — | None |
| | 5 mol ethylene oxide added at both ends of | bisphenol A | | | |
| | hydrogenated bisphenol A | | | | |
| B-24 | Dimethacrylate of polyethylene glycol, with average | Hydrogenated | — | — | None |
| | 2 mol ethylene oxide added at both ends of | bisphenol A | | | |
| | hydrogenated bisphenol A | | | | |
| B-25 | Dimethacrylate of polyethylene glycol, with average | Bisphenol A | — | — | None |
| | 5 mol ethylene oxide added at both ends of | | | | |
| | bisphenol A | | | | |
| B-26 | Dimethacrylate with average 3 mol ethylene oxide | Tricyclodecanedimethanol | — | — | None |
| | added to tricyclodecanedimethanol | | | | |

TABLE 71

| Symbol | Compound name |
|---|---|
| C-1 | 4,4′-bis(Diethylamino)benzophenone |
| C-2 | 9,10-Diphenylanthracene |

As seen in Tables 1 to 3, the developability, resolution, flexibility and foam elimination were all satisfactory with the Examples satisfying the conditions of the invention.

In contrast, satisfactory results were not obtained when the conditions were not satisfied, as shown in Table 3. Specifically, the developability was unacceptable with Comparative Example 1 and Comparative Example 4 which did not contain component (A) with a weight-average molecular weight Mw of 20,000 or lower. The foam elimination and resolution were unacceptable with Comparative Example 2 wherein n was greater than 30 and Comparative Example 3 wherein m1+m2 was greater than 10 for the compound represented by (B1) as component (B). With Comparative Example 5 which did not contain a compound represented by formula (B1) as component (B), the foam elimination was unacceptable.

The embodiments of the invention described above are not intended to place limitations on the invention, and various modifications may be incorporated herein, so as to fall within the gist of the invention.

### INDUSTRIAL APPLICABILITY

Using a photosensitive element of the invention results in satisfactory foam elimination from the developing solution after the developing device has stopped, and it is therefore highly useful as a photosensitive element to be used for formation of a resist pattern on a printed circuit board.

1. A photosensitive element comprising a support film and a photosensitive resin composition layer containing a photosensitive resin composition, formed on the support film, wherein:
the photosensitive resin composition comprises:
(A) an alkali-soluble polymer,
(B) a compound with at least one ethylenically unsaturated double bond,
(C) a sensitizing agent, and
(D) a polymerization inhibitor,
the alkali-soluble polymer (A) includes an alkali-soluble polymer in which the monomer component comprises an aromatic hydrocarbon group and which has a weight-average molecular weight Mw of 20,000 or lower, and
the compound with at least one ethylenically unsaturated double bond (B) comprises a compound having the structure represented by the following general formula (B1): 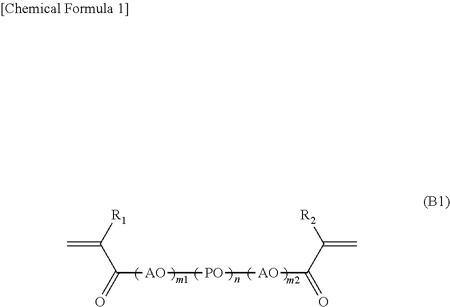
(where R₁ and R₂ each independently represent hydrogen or carbon, A is a divalent hydrocarbon group of 1 to 2 carbon atoms, P is a divalent hydrocarbon group of 3 carbon atoms, the sequence of (AO) and (PO) is random or block, m1+m2 is an integer of 0 to 10, and n is an integer of 1 to 30).

2. The photosensitive element according to claim 1, wherein n in general formula (B1) is 2 to 15.

3. The photosensitive element according to claim 1, wherein n in general formula (B1) is 3 to 8.

4. The photosensitive element according to claim 1, wherein (m1+m2)/n in general formula (B1) is less than 0.83.

5. The photosensitive element according to claim 1, wherein (m1+m2)/n in general formula (B1) is less than 0.50.

6. The photosensitive element according to claim 1, wherein the content of the compound having the structure represented by general formula (B1) is 0.1 to 10 parts by weight based on the sum of the alkali-soluble polymer (A) and the compound with an ethylenically unsaturated double bond (B).

7. The photosensitive element according to claim 1, wherein the alkali-soluble polymer (A) includes an alkali-soluble polymer which has a weight-average molecular weight Mw of 8,000 or greater.

8. The photosensitive element according to claim 1, wherein the aromatic hydrocarbon group included as the monomer component of the alkali-soluble polymer (A) is 1 to 70 parts by weight based on the total amount of the alkali-soluble polymer (A).

9. The photosensitive element according to claim 1, wherein the aromatic hydrocarbon group included as the monomer component of the alkali-soluble polymer (A) is 10 to 60 parts by weight based on the total amount of the alkali-soluble polymer (A).

10. The photosensitive element according to claim 1, wherein the compound with at least one ethylenically unsaturated double bond (B) further comprises one or more compounds having the structure represented by general formula (B2) or (B3): 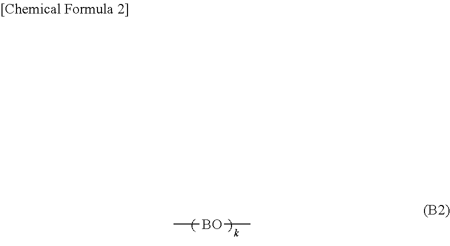
(where B is a divalent hydrocarbon group of 4 carbon atoms, and k is an integer of 1 to 30), 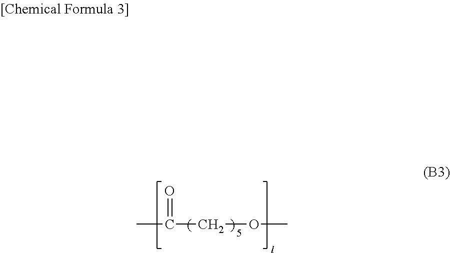
(where 1 is an integer of 1 to 30).

11. The photosensitive element according to claim 10, wherein at least one compound having the structure represented by general formula (B2) or (B3) has 3 or more ethylenically unsaturated double bonds per molecule.

12. The photosensitive element according to claim 1, which further comprises a compound comprising a hydrogenated bisphenol A structure (B4), as the compound with at least one ethylenically unsaturated double bond (B).

13. The photosensitive resin composition according to claim 1, wherein the sensitizing agent (C) includes a benzophenone compound.

14. The photosensitive element according to claim 1, wherein the polymerization inhibitor (D) includes 2,6-di-tert-butyl-para-cresol.

15. A resist pattern forming method, comprising:
a lamination step in which the photosensitive element according to claim 1 is laminated on a substrate;
an exposure step in which the photosensitive resin layer of the photosensitive resin laminate is exposed; and
a developing step in which the unexposed sections of the photosensitive resin layer are developed and removed.
